(19) United States
(12) Patent Application Publication
(10) Pub. No.: US 2025/0132689 A1
(43) Pub. Date: Apr. 24, 2025

(54) ISOLATING PROTECTION AGAINST A RISK OF ELECTROCUTION FOR AN INVERTER

(71) Applicant: Valeo eAutomotive Germany GmbH, Erlangen (DE)

(72) Inventors: Ishwar LONDHE, Erlangen (DE); Emil THOMAS, Chennai (IN); Prathap SAMRAJ, Chennai (IN); Gowtham NATARAJ, Chennai (IN)

(73) Assignee: Valeo eAutomotive Germany GmbH, Erlangen (DE)

(21) Appl. No.: 18/911,316

(22) Filed: Oct. 10, 2024

(30) Foreign Application Priority Data
Oct. 18, 2023 (DE) 10 2023 128 532.7

(51) Int. Cl. H02M 7/00; H05K 5/02

(52) U.S. Cl. CPC H02M 7/003; H05K 5/0247

(57) ABSTRACT

An inverter for a motor vehicle includes at least one lid and a main body delimiting a volume within which at least one printed circuit board is housed, the volume being closed by the lid. The inverter includes a housing which projects from the lid, the housing delimiting a space in which are housed a first connection terminal and a second connection terminal each configured to be connected to an electrical conductor intended to electrically connect an electrical energy storage means to the inverter. The housing includes a cover closing the housing, the housing having electrical insulation disposed between the cover and said connection terminals.

The present invention relates to the field of power converters used in motor vehicles. More particularly, the present invention relates to a means of electrically insulating the connection terminals of the inverter.

Vehicles, and in particular motor vehicles, are commonly equipped with an electrical energy storage means in which electrical energy is stored. This electrical energy is used to operate various vehicle components, such as a powertrain, which operate on alternating current. The vehicles are then equipped with at least one inverter to transform the electrical energy stored in the storage means into AC electrical energy.

Inverters are power electronic devices capable of generating alternating current from direct current. Inverters can be integrated into motor vehicles, particularly hybrid or electric vehicles, to convert direct current supplied by batteries into alternating current to power the electric motor.

In today's electric or hybrid vehicles, the need for electrical power implies a high-voltage supply, for example of the order of 800V.

Such inverters comprise at least one printed circuit board housed in a main body, on which several electronic components are arranged, interconnected by copper tracks formed in the thickness of the board, the inverter and by extension these electronic components being supplied with electrical current via electrical conductors.

These electrical conductors are mechanically connected to connection terminals on the inverter's printed circuit board. The connection terminals are housed in an inverter casing closed by a cover. When an operator works on the housing, the connection terminals are directly accessible, and although the electrical connection to the electrical energy storage medium has been interrupted, a residual voltage may remain within the housing at the connection terminals. This residual voltage can be dangerous for the operator, and prior art solutions do not provide sufficient protection for the operator.

The present invention fits into this context and is intended to overcome at least some of the drawbacks of the prior art. In particular, the present invention is intended to provide an inverter in which the operator is protected from the risk of electrocution when the housing is opened.

Thus, the present invention relates to an inverter for a motor vehicle comprising at least one lid and a main body delimiting a volume within which at least one printed circuit board is housed, said volume being closed by the lid, the inverter comprising a housing which projects from the lid, the housing delimiting a space in which are housed a first connection terminal and a second connection terminal each configured to be connected to an electrical conductor intended to electrically connect an electrical energy storage means to the inverter, the housing comprising a cover closing the housing, the housing comprising electrical insulation means disposed between the cover and said connection terminals.

The electrical insulation means is a protective element against electric shocks. This means of electrical insulation thus makes it possible to protect an operator working on the inverter from risks of electrocution. The connection terminals are the inverter components mechanically connected to the printed circuit board. It is understood that an electrical current from an electrical energy storage means passes successively through the electrical conductors and then the connection terminals to reach the inverter components.

The housing forms the part of the inverter within which the connection terminals are arranged, the housing being closed by the cover. When working on the housing, i.e. to reach the connection terminals, an operator accesses the connection terminals by removing the cover. Similarly, when assembling the inverter, the cover forms the element that hermetically seals the housing. The arrangement of the electrical insulation means between the connection terminals and the cover means that the connection terminals are not directly exposed when the cover is removed. Thus, when the housing is opened, if residual voltage remains in the housing for a few seconds after disconnecting the power supply to the connection terminals, the operator is protected from risks of electrocution.

According to a feature of the invention, the electrical insulation means is secured to the cover by means of a fixing member which passes through the cover. This fixing member helps sealing the housing by closing a hole in the cover. The fact that the electrical insulation means is held in place by this fixing member limits the displacement of the electrical insulation means in the housing, and also reduces the risk of the electrical insulation means being overlooked when assembling the housing and the components housed inside.

According to a feature of the invention, the electrical insulation means comprises a hole for receiving the fixing member. This hole comprises a screw thread complementary to the fixing member. Thus, the fixing member can only be installed to hermetically seal the housing if the electrical insulation means is present in the housing and correctly positioned.

According to a feature of the invention, the cover comprises a safety means configured to prevent power supply to the inverter when said cover is disengaged from the housing. The safety means makes it possible to stop the power supply to the connection terminals when the housing is without the cover. A residual voltage, i.e. an electric current persisting for a few seconds in the housing after the power supply has been switched off, cannot cause a risk of electrocution to an operator due to the presence of the electrical isolation means.

The invention also relates to a power converter intended to equip a motor vehicle comprising at least one inverter, the power converter comprising at least one electrical conductor electrically connected to one of said connection terminals, wherein the electrical insulation means is secured with at least one of said electrical conductors by at least one fastening element. By integrating the electrical insulation means into the various elements used to secure the various power converter components together, it is possible to ensure that the electrical insulation means is present and correctly positioned.

According to a feature of the invention, each electrical conductor comprises a connection element mechanically connected to one of said connection terminals, the electrical insulation means being arranged between said connection elements and the cover.

According to a feature of the invention, the fastening element prevents at least one movement of the electrical conductor relative to the housing.

According to a feature of the invention, the housing comprises at least a first barrel and a second barrel configured to receive a portion of the electrical conductor, the fastening element through at least one of said barrels.

According to a feature of the invention, the electrical insulation means is supported by at least one of said barrels. This positioning of the electrical insulating means limits the stress on the electrical insulating means. In addition, this positioning of the electrical insulation means ensures that the electrical insulation means covers both the connection terminals and the connection elements.

According to a feature of the invention, the fastening element comprises a head in contact with the electrical insulation means and a body comprising a thread, the body being received in a compartment formed in one of the electrical conductors, the compartment comprising a screw thread cooperating with the thread of the body of the fastening element.

According to a feature of the invention, the fastening element is spaced from a bottom of the compartment by a distance strictly inferior to a thickness of the electrical insulation means.

This distance between the fastening element and the bottom of the compartment ensures that the electrical insulation means is correctly positioned when the electrical conductors are attached to the housing. If the electrical insulation means is missing, the fastening element will come into abutment with the bottom of the compartment and the electrical conductor will not be optimally secured to the housing, allowing the operator to see that the electrical insulation means is missing.

The invention also relates to a method for disassembling a power converter, comprising at least:
a first step in which the cover is disengaged from the housing by removing at least the fixing member,
a second step in which the electrical insulating means is disengaged from the housing by removing at least one fastening element,
a third step in which the electrical conductors are separated from the connection terminals,
a fourth step in which the electrical conductors are extracted from the housing by sliding said electrical conductors.

It should be noted that the second step of the method for disassembling a power converter is carried out, by means of the elements used to secure the electrical insulation means to the housing, in a time interval greater than the time interval during which residual voltage remains in the housing.

Other features, details and advantages of the invention will become clearer on reading the following description on the one hand, and examples of realization given by way of indication and non-limitation with reference to the appended schematic drawings on the other hand, on which:

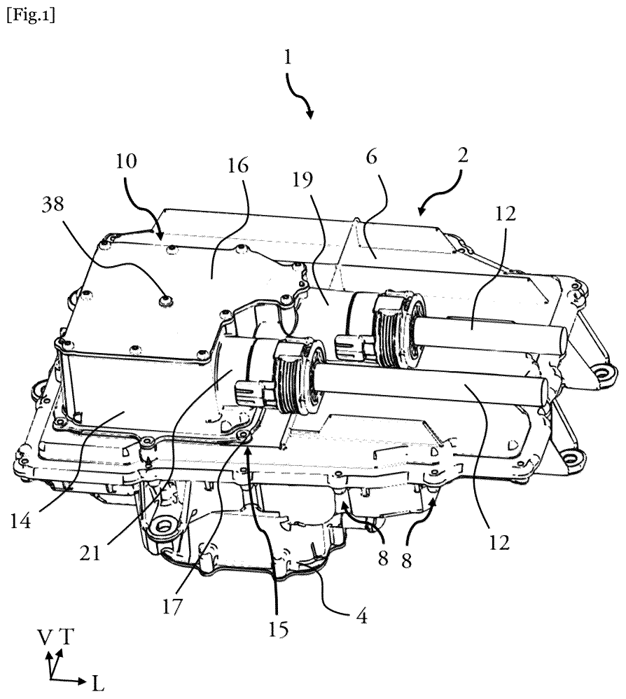

FIG. 1 shows a general view of a power converter consisting of an inverter connected to electrical conductors in a housing;

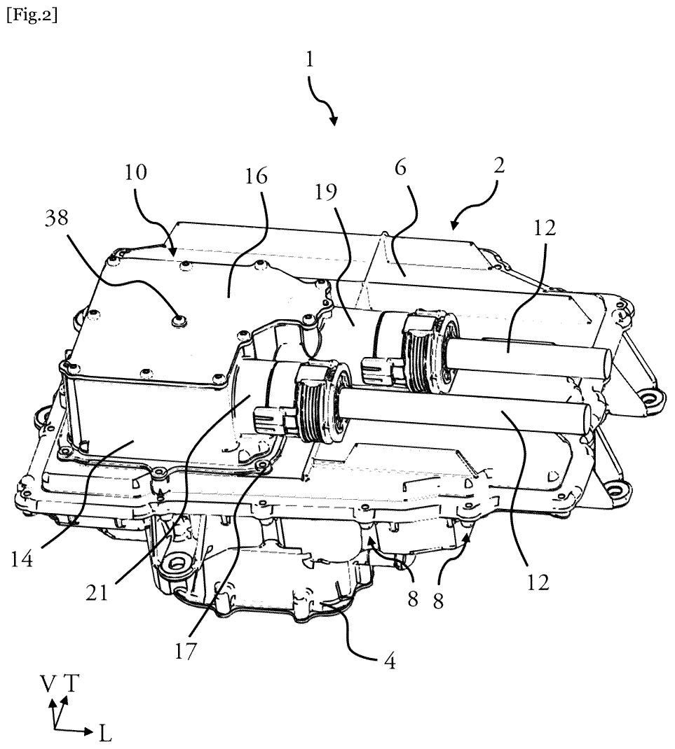

FIG. 2 shows a general view of the power converter shown in FIG. 1, in which a housing cover used to close a space in which inverter connection terminals are arranged has been removed;

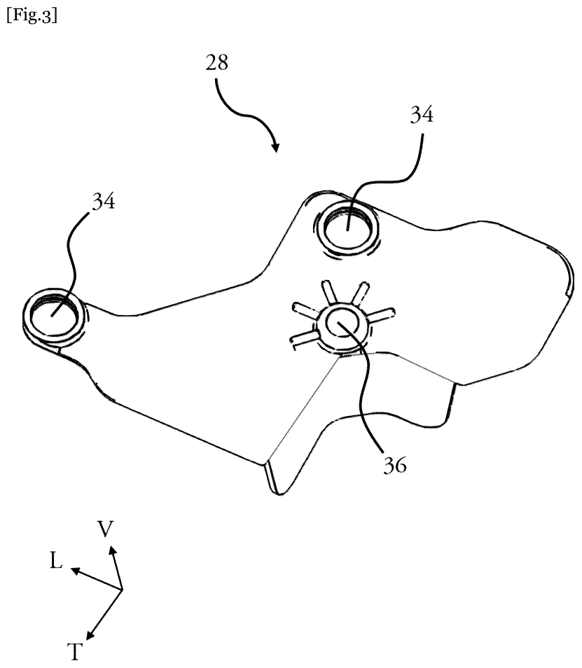

FIG. 3 shows a detail view of an electrical insulating means designed to fit into the space visible on FIG. 2 between the cover and the connection terminals;

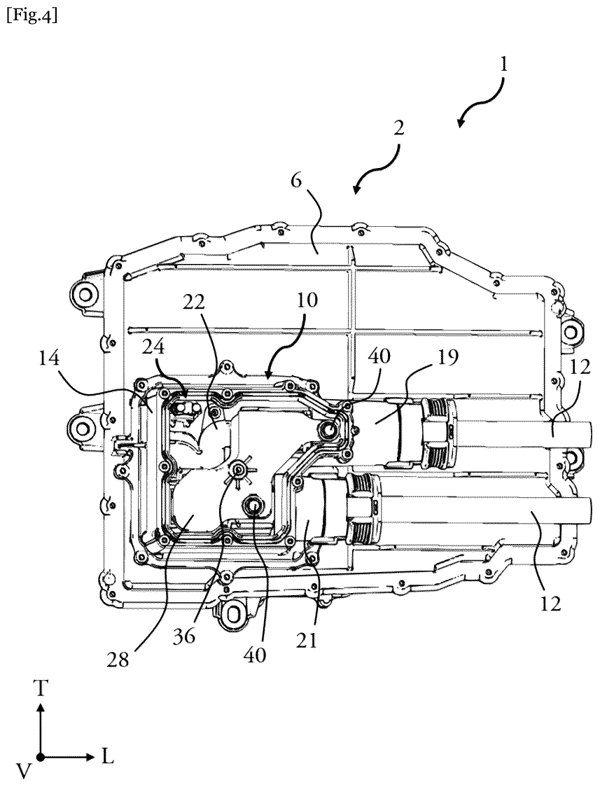

FIG. 4 shows a view of the power converter in which the housing cover has been removed and the electrical insulation means is housed in the inverter housing and secured to said housing;

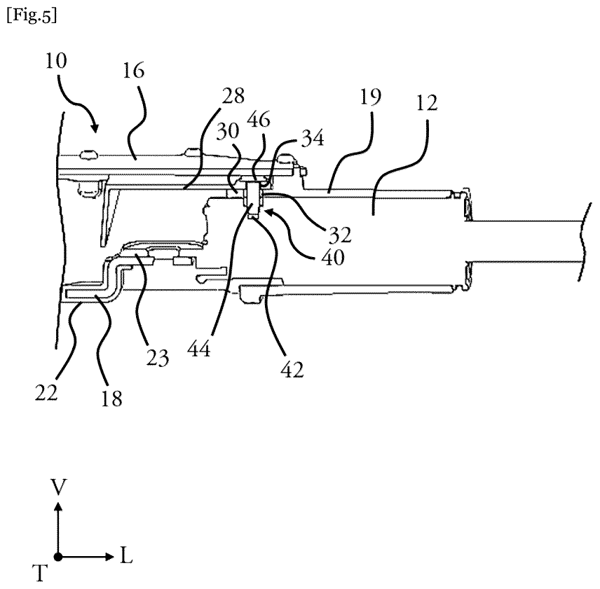

FIG. 5 shows a cross-sectional view of the power converter at a fastening element involved in securing the electrical insulation means, the housing and an electrical conductor to one another.

The features, variants and different embodiments of the invention may be associated with one another, in various combinations, insofar as they are not incompatible or mutually exclusive. In particular, it is possible to imagine variants of the invention comprising only a selection of features described hereinafter in isolation from the other features described, if this selection of features is sufficient to confer a technical advantage or to differentiate the invention from the state of the art.

In the figures, elements common to several figures retain the same reference.

In the following detailed description, the terms “longitudinal”, “transverse” and “vertical” refer to the orientation of the inverter according to the invention as arbitrarily designated by the trihedron L, V, T.

FIG. 1 shows an inverter 2 according to the present invention and intended to equip a motor vehicle. The inverter 2 consists of a main body 4 and a lid 6 delimiting a volume in which at least one printed circuit board is housed. The printed circuit board comprises a plurality of electronic components involved in the operation of the inverter 2.

The main body 4 and the lid 6 form two separate parts of the inverter 2. When the printed circuit board and the various components involved in the operation of the inverter 2 are installed in the volume delimited by the main body 4, the lid 6 is attached to the main body 4 in such a way as to seal the said volume.

The lid 6 is fastened to the main body 4 by compressing a seal between the main body 4 and the lid 6, using screws in the embodiment shown. Note that in FIG. 1, only the fastening zones 8 where the screws are used are visible.

The inverter 2 comprises a housing 10 arranged against the lid 6. The housing provides the power supply for the inverter 2. In the housing 10, electrical conductors 12 are electrically connected to connection terminals which are connected to the printed circuit board housed in the main body 4. These electrical conductors 12 enable an electrical current to be routed from an electrical energy storage means to the inverter 2. The resulting assembly of inverter 2 connected to electrical conductors 12 forms a power converter 1.

As will be described in greater detail in the following description, the connection terminals are housed in a space delimited by the housing 10. More specifically, this space is delimited by the lid 6, walls 14 extending perpendicularly to a main longitudinal and transverse plane of elongation of the lid 6, and a cover 16 secured to the walls 14. The walls 14 are arranged side by side so as to form an enclosure delimiting said space.

Remarkably, in the embodiment shown in FIG. 1, the housing 10 forms a separate component from the lid 6. To this end, the housing 10 comprises, at one end of the walls 14, fixing points 15 formed by the cooperation between eyelets 17 integral with the walls 14 and screws which are housed in the lid 6 through said eyelets 17. It should be noted that in an alternative embodiment of the invention, the walls 14 can be made of the same material as the lid 6. It is understood that in such an alternative embodiment of the invention, there is a continuity of material between the walls 14 and the lid 6, in which case the fixing points 15 are not used.

In addition, the housing 10 comprises a first barrel 19 and a second barrel 21 each projecting from the same wall 14 of the housing 10 around an axis of revolution, these axes of revolution being parallel to each other. The first barrel 19 and the second barrel 21 each accommodate an electrical conductor 12, so that a connection element for the electrical conductors 12, which will be described in greater detail in the following description, can be mechanically connected to a connection terminal.

FIG. 2 shows the power converter 1 and, more specifically, a view of the lid 6 and housing 10 of the inverter 2, without the cover 16 being visible. This view of housing 10 shows a first connection terminal 18 and a second connection terminal 20, both housed in the previously mentioned space of the housing 10. It should be noted that in the following description, references will be made to “connection terminals” when referring to the first connection terminal 18 and the second connection terminal 20.

FIG. 2 shows in particular the connection of a first connection element 23 of an electrical conductor 12 to the first connection terminal 18 and of a second connection element 25 of another electrical conductor 12 to the second connection terminal 20. The first connection element 23 and the second connection element 25 respectively form the free end of two separate electrical conductors 12 which are intended to be mechanically connected to the inverter 2.

The first connection terminal 18 and the second connection terminal 20 each comprise a first orifice 26 facing a second orifice 27 in each of the first and second connection elements 23, 25. This arrangement of the first orifice 26 of a connection terminal 18, 20 facing a second orifice 27 of a connection element 23, 25 enables a connection element 23, 25 to be joined to a connection terminal 18, 20 by means of a screw, for example, so as to enable an electric current to flow from the electrical energy storage means to the inverter 2. It should be noted that the screw enabling a connection element 23, 25 to be joined to a connection terminal 18, 20 is not shown in FIG. 2.

FIG. 2 also shows that each electrical conductor 12 is fastened to the housing 10 by means of fastening legs 30. Each fastening leg 30 is associated with a barrel 19, 21 and extends the latter into the space delimited within the housing 10. In other words, the barrels 19, 21 protrude from the wall 14 in a direction opposite to the direction along which they extend. Each fastening leg 30 comprises a first opening 32 through which a fastening element is adapted to fasten at least the housing 10 to an electrical conductor 12 extending in one of said barrels 19, 21.

The connection terminals 18, 20 are covered with an insulating coating 22 which electrically insulates the connection terminals 18, 20 from one another. This insulating coating 22 is made of an insulating polymer material which limits the risks of short-circuits between the first connection terminal 18 and the second connection terminal 20.

In addition, the housing 10 comprises a safety means 24 consisting of a first part connected to the printed circuit board and a second part formed on the cover 16. The first part of the safety means 24 comprises two connection points configured to come into contact with the second part of the cover 16 when the latter is attached to the walls 14. In fact, the cover 16 is fixed to the walls 14 by a plurality of screws, of course, if necessary, a seal is interposed between the cover 16 and the walls 14 to ensure the tightness of the housing 10.

The safety means 24 is advantageously configured to allow power supply to the inverter 2 when the cover 16 is attached to the walls 14 and to prevent power supply to the inverter 2 when the cover 16 is detached from the walls 14. It should be noted that when the power supply to the inverter 2 is cut off by removing the cover 16, a residual voltage of the order of a few seconds may remain. To this end, the inverter 2 includes an electrical isolation means 28, visible in FIGS. 3 and 4, to protect an operator working on the inverter 2.

FIGS. 3 and 4 respectively illustrate a detailed view of the electrical insulation means 28 and a view of the power converter 1 when the electrical insulation means 28 is attached to the housing 10. It should be noted that in FIG. 4, the cover 16 of the housing 10 is not visible, so that the electrical insulation means 28 is visible. This electrical insulation means 28 is designed to face the connection terminals 18, 20 and the connection elements 23, 25. To this end, the electrical insulation means 28 comprises two second openings 34, each designed to face the first opening 32 of a separate fastening leg 30.

More specifically, when the power converter 1 is assembled, the second openings 34 of the electrical insulating means 28 are on the fastening legs 30, facing the associated first opening 32, and the connecting element 23, 25 itself arranged facing said first opening 32. In this way, the fastening legs 30 are arranged between the electrical insulation means 28 and the cover 16. This arrangement enables the electrical insulating means 28 to rest on the fastening legs 30.

This alignment of a first opening 32 in a fastening leg 30 and a second opening 34 in the electrical insulating means 28 enables the fastening leg 30 to be fastened to the electrical insulating means 28 by means of a fastening element 40.

It should be noted that this connection of the electrical insulation means 28 to the housing 10 by means of a fastening element 40 will be described in greater detail in connection with FIG. 5.

Furthermore, it is remarkable that in a substantially central position, the electrical insulation means 28 comprises a hole 36. This hole 36 is intended to receive a fixing member 38, visible in FIG. 1, so as to secure the electrical insulating means 28 to the cover 16.

This fixing member 38 can be associated with a sealing member to ensure the tightness of the cover 16. In the embodiment shown, hole 36 comprises a screw thread designed to secure fixing member 38 to electrical insulation means 28. More specifically, the combination of the fixing member 38 and the hole 36 forms a control device for ensuring that the electrical insulation means 28 is correctly positioned in the housing 10 when the latter is closed. Indeed, by positioning the fixing member 38 to hermetically close the housing 10, the operator can see whether the electrical insulation means 28 is present or not. In the event that the electrical insulation means 28 is absent from the housing 10 when the operator seals the cover 16 to the walls 14, the operator will not be able to seal the housing 10 by means of the fixing member 38.

FIG. 5 shows a cross-sectional view of the power converter 1 through a vertically and longitudinally extending sectional plane. This view of the power converter 1 highlights the attachment of the electrical insulation means 28 to the housing 10 and to an electrical conductor 12.

As can be seen in FIG. 5, the electrical conductor 12 comprises a compartment 42 within which a screw thread cooperates with the fastening element 40. It is particularly noticeable in FIG. 5 that the fastening element 40 comprises a body 44 passing through a first opening 32 and the second opening 34 disposed opposite said first opening 32.

The body 44 of the fastening element 40 is housed in a compartment 42 made in an electrical conductor 12. It should be noted that what will be described in relation to the fastening element 40 shown in FIG. 5 applies mutatis mutandis to another fastening element 40 cooperating with the other first opening 32 and second opening 34 described above.

The compartment 42 has a screw thread complementary to a thread on the body 44, so that the fastening element 40 can be used to connect the electrical insulating means 28, the housing 10, via a fastening leg 30, and an electrical conductor 12 to one another. It is understood that the fastening element 40 blocks the movement of the electrical conductors 12 relative to the housing 10.

When the fastening element 40 is housed in the compartment 42, a head 46 of the fastening element 40 comes into contact with the electrical insulating means 28. This bearing of head 46 against electrical insulating means 28 compresses electrical insulating means 28 against fastening leg 30.

As shown in FIG. 5, the distance between the end of fastening element 40 located in compartment 42 and the bottom of the compartment 42 is inferior to the thickness of the electrical insulation means 28. Such a feature enables an operator to ensure that the electrical insulation means 28 is in place when assembling the housing 10 and the components within said housing 10. Indeed, in the event that an operator forgets to position the electrical insulation means 28 before inserting the fastening element 40 to secure the electrical conductor 12 to the housing 10, the fastening element 40 comes into abutment against the bottom of the compartment 42 and optimum retention of the electrical conductor 12 with the housing 10 is not ensured.

It is understood from the above that the assembly of the power converter 1 follows a method of both assembly and disassembly. When the power converter 1 is assembled, an operator wishing to disassemble the power converter 1 must then follow a method for disassembling a power converter 1 involving a first step in which the cover 16 is removed, in particular by removing the fastening element 38. Then, in a second step, the electrical insulation means 28 is removed from the housing 10 by removing at least one fastening element 40, in this case, in the embodiment shown, both fastening elements 40. In a third step of the method for disassembling the power converter 1, the electrical conductors 12 are separated from the connection terminals 18, 20, and in a fourth step, the said electrical conductors 12 are removed from the housing 10 by means of a sliding movement. It should be noted that this sliding movement is performed along the axis of revolution of each barrel 19, 21.

It should be noted that the second step of the method for disassembling the power converter 1 is carried out in a time interval greater than the time interval during which the residual voltage persists within the casing 10. In particular, this second step of the method for disassembling a power converter 1 is carried out in a time interval of at least 5 seconds. Thus, the connection terminals 18, 20 are separated from the operator by the electrical insulation means 28 during the dissipation of the residual voltage within the housing 10.

The assembly of the power converter 1 also follows a method for assembling a power converter 1 that implements steps substantially similar to the method for disassembling a power converter, starting with the fourth step. Thus, the method for assembling the power converter 1 implements a first step during which the electrical conductors 12 are inserted into the housing 10 by the barrels 19, 21 by means of a sliding movement. Then, in a second step of the method for assembling, the electrical conductors 12 are placed opposite the connection terminals 18, 20. More specifically, in this second step, the second orifices 27 of the connection elements 23, 25 each come opposite a first orifice 26 of the connection terminals 18, 20. In a third step of the process for assembling the power converter 1, the electrical insulation means 28 is positioned on the housing 10. Then, in a fourth step, at least one fastening element 40 is positioned. This positioning of the fastening element 40 is carried out so that, in accordance with what has been described previously, the housing 10, the electrical insulation means 28 and an electrical conductor 12 are secured to one another.

The present invention achieves its intended purpose by offering an inverter in which the risks of electrocution for an operator working on an inverter housing in which connection terminals are housed are limited. This risk of electrocution is limited by an electrical insulation means arranged between the connection terminals and a cover of the housing.

The present invention, however, is not limited to the means and configurations described and illustrated herein, and extends equally to any equivalent means and configurations, as well as to any technically operative combination of such means.

1. Inverter for a motor vehicle comprising at least one lid and a main body delimiting a volume within which at least one printed circuit board is housed, said volume being closed by the lid, the inverter comprising a housing which projects from the lid, the housing delimiting a space in which are housed a first connection terminal and a second connection terminal each configured to be connected to an electrical conductor intended to electrically connect an electrical energy storage means to the inverter, the housing comprising a cover closing the housing, the housing comprising electrical insulation means disposed between the cover and said connection terminals.

2. Inverter according to claim 1, wherein the electrical insulation means is secured to the cover by means of a fixing member which passes through the cover.

3. Inverter according to claim 2, wherein the electrical insulation means comprises a hole for receiving the fixing member.

4. Inverter according to claim 1, wherein the cover comprises a safety means configured to prevent power supply to the inverter when said cover is disengaged from the housing.

5. Power converter intended to equip a motor vehicle comprising at least one inverter according to claim 1, the power converter comprising at least one electrical conductor electrically connected to one of said connection terminals, wherein the electrical insulation means is secured with at least one of said electrical conductors by at least one fastening element.

6. Power converter according to claim 5, wherein each electrical conductor comprises a connection element mechanically connected to one of said connection terminals, the electrical insulation means being arranged between said connection elements and the cover.

7. Power converter according to claim 5, wherein the fastening element prevents at least one movement of the electrical conductor relative to the housing.

8. Power converter according to claim 5, wherein the housing comprises at least a first barrel and a second barrel configured to receive a portion of the electrical conductor, the fastening element through at least one of said barrels.

9. Power converter according to claim 8, wherein the electrical insulation means is supported by at least one of said barrels.

10. Power converter according to claim 5, wherein the fastening element comprises a head in contact with the electrical insulation means and a body comprising a thread, the body being received in a compartment formed in one of the electrical conductors, the compartment comprising a screw thread cooperating with the thread of the body of the fastening element.

11. Power converter according to claim 10, wherein one end of the fastening element is spaced from a bottom of the compartment by a distance strictly inferior to a thickness of the electrical insulation means.

12. Method for disassembling a power converter according to claim 5, comprising at least:
a first step in which the cover is disengaged from the housing by removing at least the fixing member,
a second step in which the electrical insulating means is disengaged from the housing by removing at least one fastening element,
a third step in which the electrical conductors are separated from the connection terminals,
a fourth step in which the electrical conductors are extracted from the housing by sliding said electrical conductors.

13. Inverter according to claim 2, wherein the cover comprises a safety means configured to prevent power supply to the inverter when said cover is disengaged from the housing.

14. Power converter intended to equip a motor vehicle comprising at least one inverter according to claim 2, the power converter comprising at least one electrical conductor electrically connected to one of said connection terminals, wherein the electrical insulation means is secured with at least one of said electrical conductors by at least one fastening element.

15. Power converter according to claim 6, wherein the fastening element prevents at least one movement of the electrical conductor relative to the housing.

16. Power converter according to claim 6, wherein the housing comprises at least a first barrel and a second barrel configured to receive a portion of the electrical conductor, the fastening element through at least one of said barrels.

17. Power converter according to claim 6, wherein the fastening element comprises a head in contact with the electrical insulation means and a body comprising a thread, the body being received in a compartment formed in one of the electrical conductors, the compartment comprising a screw thread cooperating with the thread of the body of the fastening element.

18. Method for disassembling a power converter according to claim 6, comprising at least:
a first step in which the cover is disengaged from the housing by removing at least the fixing member,
a second step in which the electrical insulating means is disengaged from the housing by removing at least one fastening element,
a third step in which the electrical conductors are separated from the connection terminals,
a fourth step in which the electrical conductors are extracted from the housing by sliding said electrical conductors.

19. Inverter according to claim 3, wherein the cover comprises a safety means configured to prevent power supply to the inverter when said cover is disengaged from the housing.

20. Power converter intended to equip a motor vehicle comprising at least one inverter according to claim 3, the power converter comprising at least one electrical conductor electrically connected to one of said connection terminals, wherein the electrical insulation means is secured with at least one of said electrical conductors by at least one fastening element.
